(19) United States
(12) Patent Application Publication
(10) Pub. No.: US 2024/0383783 A1
(43) Pub. Date: Nov. 21, 2024

(54) DOPED DIAMOND PARTICLE-BASED THREE-DIMENSIONAL ELECTRODE FOR WATER TREATMENT AND PREPARATION METHOD THEREFOR

(71) Applicant: HU-NAN NEW FRONTIER SCIENCE & TECHNOLOGY LTD., Changsha (CN)

(72) Inventors: Qiuping WEI, Changsha (CN); Haiping SHI, Changsha (CN); Yingjie SHI, Changsha (CN); Shuai SHI, Changsha (CN); Zhen SHI, Changsha (CN); Kechao ZHOU, Changsha (CN); Jilin TAN, Changsha (CN); Baofeng WANG, Changsha (CN)

(73) Assignee: HU-NAN NEW FRONTIER SCIENCE & TECHNOLOGY LTD., Changsha (CN)

(21) Appl. No.: 18/694,433

(22) PCT Filed: Nov. 5, 2021
(86) PCT No.: PCT/CN2021/128996

§ 371 Date: Mar. 22, 2024

(30) Foreign Application Priority Data
Sep. 22, 2021 (CN) 202111106654.9

(51) Int. Cl. C02F 1/469; C30B 25/18

(52) U.S. Cl. CPC C02F 1/469; C30B 25/18

(57) ABSTRACT

A doped diamond particle-based three-dimensional electrode for water treatment and a preparation method therefor are provided. A boron-doped diamond plate electrode is used as an anode electrode, a titanium plate is used as a cathode electrode, and doped diamond particles are used as a filler that is assembled to form a filler module. The doped diamond particles include a core material, and a doped diamond film coating the core material. The doping element is one or more selected from boron, nitrogen, phosphorus, and lithium; and the core material is at least one selected from diamond particles, boron-doped diamond particles, metal particles, and ceramic particles. Doped diamond particles having a loose porous structure are used as a filler, to greatly increase the electrochemical active area and the adsorbable area.

### CROSS REFERENCE TO THE RELATED APPLICATIONS

This application is the national phase entry of International Application No. PCT/CN2021/128996, filed on Nov. 5, 2021, which is based upon and claims priority to 202111106654.9, filed on Sep. 22, 2021, in China, the entire contents of which are incorporated herein by reference.

### TECHNICAL FIELD

The present invention relates to the technical field of diamond electrode preparation, and in particular to a doped diamond particle-based three-dimensional electrode for water treatment and a preparation method therefor.

### BACKGROUND

Diamond film electrode is a material with excellent physical and chemical properties. Due to the high mechanical strength, excellent chemical stability and electrochemical performance, and its surface that will not change obviously under high-intensity current load, the diamond film electrode has a broad prospect in electrochemical applications. In the growth process of a diamond film, boron is doped such that the prepared diamond film becomes a semiconductor or a conductor presenting metallic behaviors. The boron-doped diamond electrode obtained by depositing it on the surface of some electrode substrates such as a titanium sheet, a silicon sheet, and graphite is a focus of research in sewage purification and treatment, electrochemical biosensors and other fields in recent years. Compared with traditional electrodes, the boron-doped diamond electrode (BDD) that is a thin film electrode has many advantages, such as wide window, low background current, good electrochemical stability, good mechanical properties, strong corrosion resistance, good conductivity and so on, and has a good prospect in the field of electrochemical oxidation treatment of sewage.

### SUMMARY

### Technical Problem

The traditional plate electrode is a two-dimensional electrode having a real electrode area close to the apparent electrode area. The low specific surface area of the electrode seriously restricts the mass transfer efficiency through the electrode surface.

### Technical Solution

In view of the shortcomings of the prior art, an object of the present invention is to provide a doped diamond particle-based three-dimensional electrode for water treatment and a preparation method therefor.

To achieve the above objective, the following technical solutions are adopted in the present invention.

The present invention provides a doped diamond particle-based three-dimensional electrode for water treatment. The three-dimensional electrode for water treatment includes an anode, a cathode, and a filler. The filler is doped diamond particles. The doped diamond particles include a core material, and a doped diamond film coating the core material. The doping element is one or more selected from boron, nitrogen, phosphorus, and lithium, and preferably, boron.

The present invention provides a three-dimensional electrode. In the three-dimensional electrode, doped diamond particles having a loose porous structure are provided and used as a filler, to greatly increase the electrochemical active area and the adsorbable area. Further, the filler generates a micro-current due to the electric polarization between the cathode and the anode, so that the three-dimensional electrode attains a high current density at a low voltage, thereby improving the performance of electro-catalysis to generate an active intermediate.

According to a preferred embodiment, the anode is a boron-doped diamond plate electrode, the cathode is a titanium plate, and the filler is assembled to form a filler module.

When the boron-doped diamond plate electrode is used as an anode and the titanium plate is used as a cathode, the three-dimensional electrode has the maximum electrode density and the most excellent electrocatalytic performance.

According to a preferred embodiment, the core material is at least one selected from diamond particles, boron-doped diamond particles, metal particles, and ceramic particles. The metal in the metal particles is one selected from nickel, niobium, copper, titanium, cobalt, tungsten, molybdenum, chromium, and iron or an alloy thereof. The ceramic in the ceramic particles is at least one selected from Al₂O₃, ZrO₂, SiC, Si₃N₄, BN, B₄C, AlN, WC, and Cr₇C₃. The core material has a regular or irregular shape with a size of 100 nm to 50 μmm.

Further preferably, the core material is at least one selected from diamond particles, boron-doped diamond particles, SiC particles, and titanium particles. The particle sizes of the diamond particles and the boron-doped diamond particles are 100-500 μm, and the particle sizes of the SiC particles and the titanium particles are 200 nm-30 μmm, preferably 2-8 μmm, and further preferably 3-5 μmm.

The present inventor finds that when the core material is at least one selected from diamond particles, boron-doped diamond particles, SiC particles, and titanium particles, the particle sizes of the diamond particles and the boron-doped diamond particles are 100-500 μm, and the particle sizes of the SiC particles and the titanium particles are 200 nm-30 μmm, the electrocatalytic performance of the final three-dimensional electrode is better.

In the present invention, the boron-doped diamond particles or diamond particles used are preferably particles with a single crystal structure formed at a high temperature under a high pressure, which has low cost and excellent electrocatalytic activity in cooperation with the doped polycrystalline diamond films. The boron-doped diamond particles or diamond particles and the doped diamond film have similar crystal structures, so they are not only easy to nucleate in preparation, but also stably associated, to provide more excellent performances synergistically. Through a large number of creative experiments, the present inventor finds that the doped diamond particles formed with spherical SiC particles and titanium particles as a core material have excellent electrocatalytic activity compared with other metals or ceramics and other shapes.

Further preferably, the core material is one selected from irregular boron-doped diamond particles of 100-500 μm or silicon carbide particles, and preferably boron-doped diamond particles and spherical structures of 2 μmm-8 μmm.

The present inventor finds surprisingly that when the filler is a mixed filler consisting of a filler A and a filler B where the core material of the filler A is selected from irregular boron-doped diamond particles of 100-500 μm and the core material of the filler B is selected from spherical SiC particles of 200 nm-30 μmm, the energy consumption for degradation by the final three-dimensional electrode is greatly reduced.

According to a preferred embodiment, the thickness of the doped diamond film is 5 nm-20 μm, and preferably 1-10 μm, and the crystal structure is polycrystalline.

According to a preferred embodiment, the dopant density in the doped diamond film is >10²¹ cm⁻³, and preferably 10²¹ cm⁻³-10²² cm⁻³.

When the content in the doped diamond film is controlled in the above range, the finally obtained doped diamond particles have the most preferred performance. This is because when the dopant density is greater than 10¹⁸ cm⁻³, the insulating diamond has semiconductor properties and when the dopant density is greater than 10²¹ cm⁻³, metal-like properties can be obtained. However, due to the different lattice coefficients of the doped element and diamond, too much doping will lead to the destruction of the diamond lattice and the generation of impurity phases (such as sp²), causing the loss of some excellent properties of diamond, such as high hardness, high strength, and inert surface. By controlling the dopant density in the doped diamond film in the above range, the most preferred performances can be obtained in cooperation with the core material of the carrier particles.

The present inventor finds that by setting the content in the doped diamond film in the above range, doped diamond particles with completely uniform coating and most preferred performances can be obtained.

According to a preferred embodiment, the doping method of the doped diamond film includes one of constant doping, multi-layer variable doping and gradient doping or a combination thereof.

Further preferably, when diamond particles and boron-doped diamond particles are used as a core material, the doping method of the doped diamond film coated on the surface of the core material is gradient doping, and the dopant density increases from the inside to the outside.

The bottom layer in contact with the diamond layer is doped with a minor amount of an element, to maintain purity and ensure the thermal conductivity, and then the dopant density of the element is gradually increased, so that the top layer has a higher content of doping element, and has excellent hydrophilicity when high-temperature heat treatment is included.

Further preferably, when the SiC particles are used as a core material, the doping method of the doped diamond film coated on the surface of the core material is gradient doping, and the dopant density decreases from the inside to the outside. In the present invention, a doped diamond layer with a doping element content decreasing over gradients is provided on the surface of SiC particles. The doping element content is the highest at the bottom layer in contact with the substrate, and the electrical conductivity is the highest, so that the SiC particles can be endowed with higher conductivity.

The present inventor finds that when both irregular doped diamond particles and spherical SiC particles are used as a filler and the above two gradient doping methods are adopted, the final electrocatalytic activity is the highest and the energy consumption is the lowest.

According to a preferred embodiment, the doped diamond film is a porous doped diamond film, and the pore size in the doped diamond film is 10 nm-200 nm.

By providing micropores on the surface of the doped diamond film, the specific surface area of the particles can be further increased and the performances are improved.

According to a preferred embodiment, a modification layer is provided on the surface of the coating layer. The modification layer is one selected from end group modification, metal modification, carbon material modification, and organic modification, or a combination thereof.

The electrocatalytic activity of the particles with the modification layer can be further improved by providing the modification layer on the surface of the coating layer.

The present invention provides a method for preparing a doped diamond particle-based three-dimensional electrode for water treatment. The method includes:
Step 1: preparation of doped diamond particles, including
planting nano-diamond seed crystal on the surface of the core material, and then growing a doped diamond film on the core material planted with the diamond seed crystal by chemical vapor deposition to obtain doped diamond particles, where the growth pressure is 2-5 Kpa; the growth temperature is 800-850° C.; the growth process is repeated 2-6 times, and between experiments, the carrier particles were taken out to shake for a while and then put back in the furnace, and each deposition continued for 3-6 hrs; and the doping gas source is at least one selected from phosphine, ammonia, and borane; and
Step 2: preparation of three-dimensional electrode for water treatment, including
assembling the doped diamond particles into a filler module through a fixed bed or a fluidized bed, and using a boron-doped diamond plate electrode as an anode electrode and a titanium plate as a cathode electrode to obtain the three-dimensional electrode for water treatment.

According to a preferred embodiment, in Step 1, the chemical vapor deposition is hot filament chemical vapor deposition, and the temperature of the hot filament is 2500-2700° C.

According to a preferred embodiment, in Step 1, when the doping mode is constant doping, during the chemical vapor deposition, the ratio of the mass flow rate of the gases introduced is hydrogen: methane:doping gas source=98:2:0.3-0.6.

According to a preferred embodiment, in Step 1, when the doping mode is gradient doping and the dopant density increases from the inside to the outside, during the chemical vapor deposition, the growth time is repeated three times; during the first growth and deposition process, the ratio of the mass flow rate of the gases introduced is controlled such that hydrogen: methane:doping gas source=98:2: 0.1-0.3; during the second growth and deposition process, the ratio of the mass flow rate of the gases introduced is controlled such that hydrogen: methane:doping gas source=98:2: 0.4-0.6; and during the third growth and deposition process, the ratio of the mass flow rate of the gases introduced is controlled such that hydrogen: methane:doping gas source=98:2: 0.7-1.0.

According to a preferred embodiment, in Step 1, when the doping mode is gradient doping and the dopant density decreases from the inside to the outside, during the chemical vapor deposition, the growth time is repeated three times; during the first growth and deposition process, the ratio of the mass flow rate of the gases introduced is controlled such that hydrogen: methane:doping gas source=98:2: 0.7-1.0; during the second growth and deposition process, the ratio of the mass flow rate of the gases introduced is controlled such that hydrogen: methane:doping gas source=98:2: 0.4-0.6; and during the third growth and deposition process, the ratio of the mass flow rate of the gases introduced is controlled such that hydrogen: methane:doping gas source=98:2: 0.1-0.3.

According to a preferred embodiment, in Step 1, the doped diamond particles are etched, to obtain a porous doped diamond film. The etching process includes: sputtering metal nickel on the surface of the doped diamond film by magnetron sputtering, and then carrying out heat treatment.

In addition, depending on the practical application scenario, after the heat treatment, nickel particles can be removed from the pores by using a boiling nitric acid solution.

Further preferably, the process parameters for sputtering the metal nickel include argon introduced and adjusted to a pressure of 1-3 Pa, sputtering current of 250-350 μmA, and sputtering time of 10-30 s. The thickness of the sputtered Ni layer is 5-10 nm, and the gas pressure is maintained at 7-15 kPa.

Further preferably, the temperature for the heat treatment is 800-900° C., the time for the heat treatment is 3-5 hrs, and the ratio of mass flow rates of atmospheres introduced is H₂:Ar=1.5.

Further preferably, the nitric acid solution is mixed with concentrated nitric acid and water in a volume ratio of 1-4:4.

The present inventor finds that the carrier particles can be well coated by multiple times of growth, by lowering the temperature, removing the carrier particles, then further raising the temperature to the target temperature, after each 3-6 hrs of growth. In this way, the finally obtained doped diamond particles have the most preferred performance.

According to a preferred embodiment, in Step 1, the process of planting nano-diamond seed crystal on the surface of the core material includes: immersing the core material in a suspension containing nano-diamond, ultrasonically shaking for >30 μmin, and finally cleaning drying to obtain the product. In the suspension containing nano-diamond, the mass fraction of nano-diamond is 0.01-0.1 wt %.

According to a preferred embodiment, in Step 1, the doped diamond particles are etched, to obtain a porous doped diamond film. The etching process includes at least one of high-temperature atmosphere etching, high-temperature metal etching, and plasma etching.

According to a preferred embodiment, in Step 2, the fixed bed is assembled by fixing doped diamond particles between the cathode electrode and the anode electrode in the left-to-right direction by a Nafion film to form a filler module, or fixing diamond particles by a Nafion film to form a module, inserting the cathode electrode into the Nafion film, and arranging the anode electrode at the right side of the electrode module.

According to a preferred embodiment, in Step 2, the fluidized bed is assembled by sandwiching doped diamond particles between the anode electrode and the cathode electrode in the top-to-bottom direction without fixation, or loading doped diamond particles in a cathode electrode frame and inserting the anode electrode rod into the cathode frame.

### Beneficial Effects

The present invention provides a three-dimensional electrode for water treatment. A boron-doped diamond plate electrode is used as an anode electrode, a titanium plate is used as a cathode electrode, and doped diamond particles are used as a filler that is assembled to form a filler module. In the present invention, the doped diamond particles having a loose porous structure are used as a filler, to greatly increase the electrochemical active area and the adsorbable area. Further, the filler generates a micro-current due to the electric polarization between the cathode and the anode, so that the three-dimensional electrode attains a high current density at a low voltage, thereby improving the performance of electro-catalysis to generate an active intermediate.

According to the invention, vapor deposition is adopted in the growth process. For example, for a boron-doped diamond film, polycrystalline diamond is prepared by vapor deposition by introducing hydrocarbons such as methane (CH₄) and acetylene, hydrogen (H₂) and borane into a reaction chamber. The gas concentration is adjustable and the ratio is uniform. Therefore, the boron-doped diamond film prepared by the vapor deposition method has highly uniformly doped B, and the preparation of a high-B film can be easily realized. In the present invention, multiple growth processes are employed and the crystal structure, the film thickness and the doping amount are effectively controlled, such that the performances of the finally obtained doped diamond particles are most excellent.

### BRIEF DESCRIPTION OF THE DRAWINGS

FIG. 1(a)-FIG. 1(c) show the microstructure of boron-doped diamond particles prepared in Example 1, in which (a) is an SEM image of boron-containing diamond with a single crystal structure coated with polycrystalline B-doped diamond film; (b) is an enlarged view of a polycrystalline boron-doped diamond film; and (c) is a Raman spectrum of a polycrystalline diamond film.

FIG. 2 shows a fixed bed assembly mode of a filler module in Example 1.

FIG. 3 shows a fixed bed assembly mode of a filler module in Example 2.

FIG. 4 shows a fluidized bed assembly mode of a filler module in Example 3.

FIG. 5 shows a fluidized bed assembly mode of a filler module in Example 4.

FIG. 6 is a schematic diagram of a three-dimensional electrode used in Example 9. In the drawings, 1. reaction tank; 2. anode plate; 3. cathode plate; 4. power source; 5. reaction chamber; 6. electrode particles; 7. water inlet; 8. water outlet; 9. aeration disc; 10. gas duct; 11. gas supply structure; 12. chute; 13. first slot; 14. second slot; 15. first engaging block; 16. positive lead; 17. negative lead.

FIG. 7 is a schematic diagram of a three-dimensional electrode used in Example 10, in which 1. reaction tank; 2. power source; 3. insulating mesh board; 4. anode rod; 5. cathode mesh tube; 6. reaction chamber; 7. aeration chamber; 8. particulate electrode; 9. water intake passage; 10. aeration disc; 11. gas duct; 12. gas supply structure; 13. insulating top cover; 14. lead hole; 15. water inlet; 16. water outlet.

### DETAILED DESCRIPTION OF THE EMBODIMENTS

### Example 1

### Step 1: Preparation of Doped Diamond Particles

(1) Boron-containing diamond particles with an average particle size of 3 μmm were washed.
(2) Then, they were immersed in a suspension containing nano-diamond, ultrasonically shaken for 30 μmin, washed and dried. In the suspension containing nano-diamond, the mass fraction of nano-diamond was 0.1 wt %.
(3) A boron-doped diamond film was deposited by hot-filament CVD. The deposition process parameters were as follows. The hot-filament distance was 6 μmm, the growth temperature was 820° C., the hot-filament temperature was 2200° C., the deposition pressure was 4 KPa, and the volume ratio was hydrogen: methane: borane=98:2: 0.5. The thickness of the diamond film was 10 m by controlling the deposition time. The growth process was repeated 4 times. Between experiments, the carrier particles were taken out to shake for a while and then put back in the furnace, and each deposition continued for 4 hours.

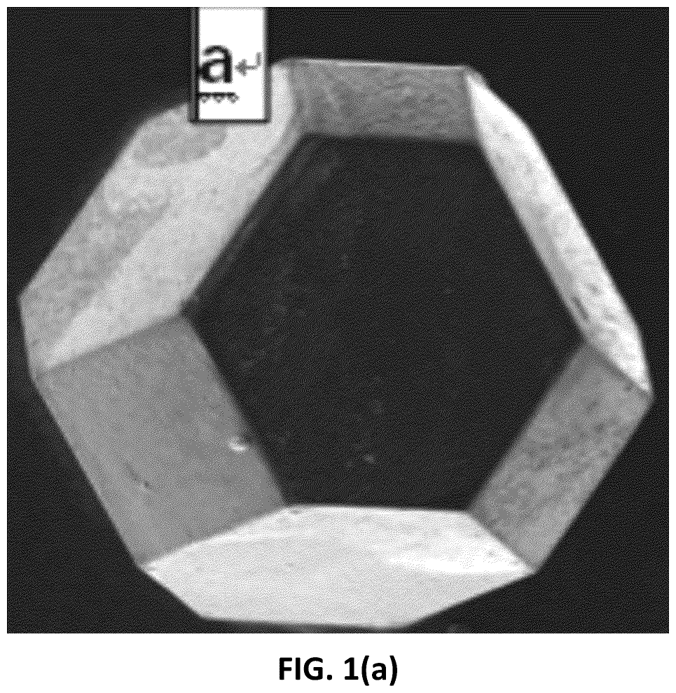

FIG. 1(a) is an SEM image of a single crystal B-doped diamond coated with a polycrystalline B-doped diamond film. FIG. 1(b) is an enlarged view of a polycrystalline film. FIG. 1(c) is a Raman spectrum of a polycrystalline diamond film. In the spectrum, typical B peaks (479 cm⁻¹ and 1200 cm⁻¹) appear again, few graphite (G peak: 1530 cm⁻¹) is present, and the B content is fitted to be greater than 10²¹ cm⁻¹, showing that it is a material heavily doped with B.

### Step 2: Assembly of a Three-Dimensional Electrode

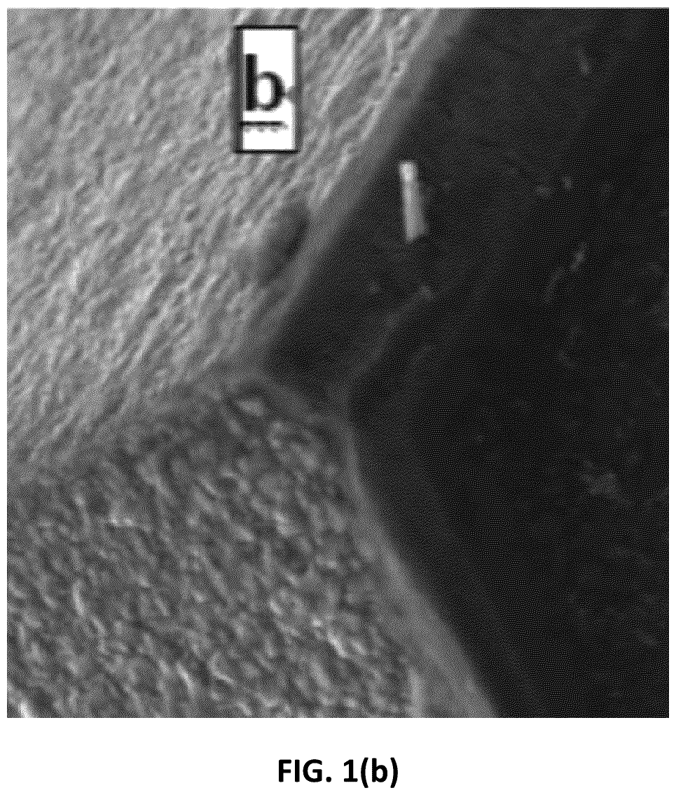

100 g of doped diamond particles having a diameter of 3 μmm (a total specific surface area of 375 cm²) was weighed and fixed between the cathode electrode and the anode electrode in the left-to-right direction by a Nafion film to form a filler module, as shown in FIG. 2. A boron-doped diamond plate electrode was used as the anode and a titanium plate was used as the cathode. Then, in a three-dimensional electrolysis system for water treatment, the module described in this example was used to degrade 1 L of a glucose solution with an initial COD of about 9000 μmg/L for 4 hrs, during which the degradation current was 1.5 A. The COD removal rate reached 99.9%, and the energy consumption per ton of water was about 19.8 kWh/m³. The energy consumption per ton of water by a two-dimensional electrode without the filler was 31.00 kWh/m³. It can be seen that the energy consumption is reduced by about 36.1% after the filler is added.

### Example 2

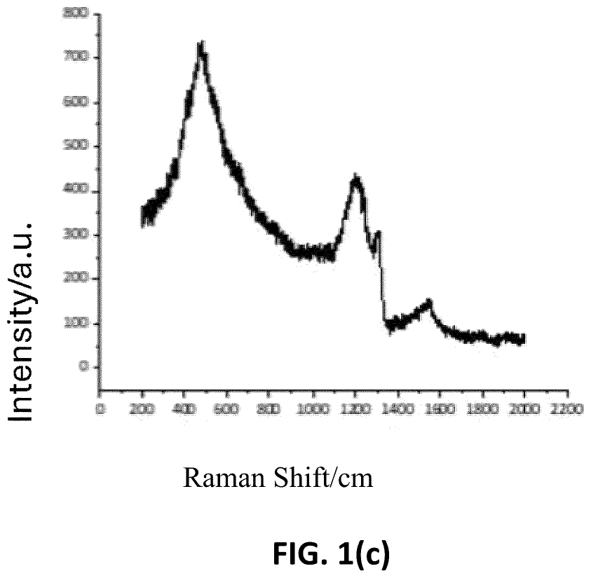

The preparation of doped diamond particles in Example 2 was the same as that in Example 1, except that the doped diamond particles were fixed by a Nafion film to form a module, the cathode electrode was inserted into the Nafion film, and the anode electrode was arranged at the right side of the electrode module, as shown in FIG. 3. Then, in a three-dimensional electrolysis system for water treatment, the module described in this example was used to degrade 1 L of a glucose solution with an initial COD of about 9000 μmg/L for 3.5 hrs, during which the degradation current was 1.5 A. The COD removal rate reached 99.9%, and the energy consumption per ton of water was 18 kWh/m³. The energy consumption per ton of water by a two-dimensional electrode without the filler was 31.00 kWh/m³. The energy consumption per ton of water is reduced by about 41% compared with the plate electrode.

### Example 3

### Step 1: Preparation of Doped Diamond Particles

Spherical silicon carbide having a diameter of 3 μmm was used as the core material. The core material was immersed in a suspension containing nano-diamond, ultrasonically shaken for 30 μmin, washed and dried. In the suspension containing nano-diamond, the mass fraction of nano-diamond is 0.01 wt %.

A boron-doped diamond film was deposited by hot-filament CVD. The deposition process parameters were as follows. The hot-filament distance was 6 μmm, the growth temperature was 800° C., the hot-filament temperature was 2200° C., and the deposition pressure was 3 KPa. The thickness of the diamond film was 1 μm by controlling the deposition time. During the chemical vapor deposition, the ratio of the mass flow rate of the gases introduced was hydrogen: methane: borane=98:2: 0.3. The growth pressure was 2 Kpa. The growth process was repeated 2 times. Between experiments, the carrier particles were taken out to shake for a while and then put back in the furnace, and each deposition continued for 6 hrs.

### Step 1: Assembly of a Three-Dimensional Electrode

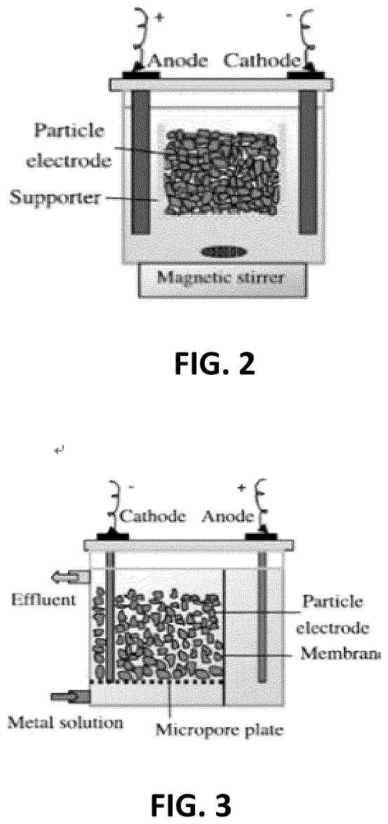

100 g of doped diamond particles having a diameter of 3 μmm was sandwiched between the anode electrode and the cathode electrode in the top-to-bottom direction without fixation (as shown in FIG. 4). A boron-doped diamond plate electrode was used as the anode and a titanium plate was used as the cathode. Then, in a three-dimensional electrolysis system for water treatment, the module described in this example was used to degrade 1 L of a glucose solution with an initial COD of about 9000 μmg/L for 4 hrs. The COD removal rate reached 99.9%, and the energy consumption per ton of water was about 21 kWh/m³. The energy consumption per ton of water by a two-dimensional electrode without the filler was 31.00 kWh/m³. The energy consumption was reduced by 33.12%.

### Example 4

The conditions were the same as those in Example 3, except that the core material in the prepared doped diamond particles was spherical silicon carbide having a diameter of 10 μmm.

100 g of doped diamond particles having a diameter of 10 μmm was sandwiched between the anode electrode and the cathode electrode in the top-to-bottom direction without fixation (as shown in FIG. 4). A boron-doped diamond plate electrode was used as the anode and a titanium plate was used as the cathode. Then, in a three-dimensional electrolysis system for water treatment, the module described in this example was used to degrade 1 L of a glucose solution with an initial COD of about 9000 μmg/L for 4 hrs, during which the current was 1.5 A. The COD removal rate reached 99.9%, and the energy consumption per ton of water was about 26.7 kWh/m³. The energy consumption per ton of water by a two-dimensional electrode without the filler was 31.00 kWh/m³. The energy consumption was reduced by about 13.87% compared with a two-dimensional electrode without the filler.

### Example 5

The conditions were the same as those in Example 3, except that the core material in the prepared doped diamond particles was spherical silicon carbide having a diameter of 1 μmm.

100 g of doped diamond particles having a diameter of 1 μmm was sandwiched between the anode electrode and the cathode electrode in the top-to-bottom direction without fixation (as shown in FIG. 4). A boron-doped diamond plate electrode was used as the anode and a titanium plate was used as the cathode. Then, in a three-dimensional electrolysis system for water treatment, the module described in this example was used to degrade 1 L of a glucose solution with an initial COD of about 9000 μmg/L for 4 hrs, during which the degradation current was 1.5 A. The COD removal rate reached 99.9%, and the energy consumption per ton of water was about 25.0 kWh/m³. The energy consumption per ton of water by a two-dimensional electrode without the filler was 31 kWh/m³. The energy consumption was reduced by 19.31% compared with a two-dimensional electrode without the filler.

### Example 6

### Step 1: Preparation of Boron Doped Diamond Particles

Spherical titanium having a diameter of 5 μmm was used as the core material. The core material was immersed in a suspension containing nano-diamond, ultrasonically shaken for 30 μmin, washed and dried. In the suspension containing nano-diamond, the mass fraction of nano-diamond was 0.1 wt %.

A boron-doped diamond film was deposited by hot-filament CVD. The deposition process parameters were as follows. The hot-filament distance was 6 μmm, the growth temperature was 850° C., the hot-filament temperature was 2200° C., the deposition pressure was 4 KPa, and the volume ratio was hydrogen: methane: borane=98:2: 0.5. The thickness of the diamond film was 2 m by controlling the deposition time. The growth process was repeated 4 times. Between experiments, the carrier particles were taken out to shake for a while and then put back in the furnace, and each deposition continued for 4 hrs.

The boron doped diamond particles were etched, to obtain a porous boron doped diamond film. The etching process was as follows. Metal nickel was sputtered on the surface of the boron doped diamond film by magnetron sputtering. The process parameters for sputtering the metal nickel include argon introduced and adjusted to have a pressure of 3 Pa, sputtering current of 350 mA, and sputtering time of 10 s. The thickness of the sputtered Ni layer was 7 nm, and then heat treatment was carried out. The gas pressure was maintained at 12 kPa. The temperature for heat treatment was 900° C., the time for the heat treatment was 3 hrs, and the ratio of mass flow rates of atmospheres introduced was H₂:Ar=1.5.

### Step 2: Assembly of a Three-Dimensional Electrode

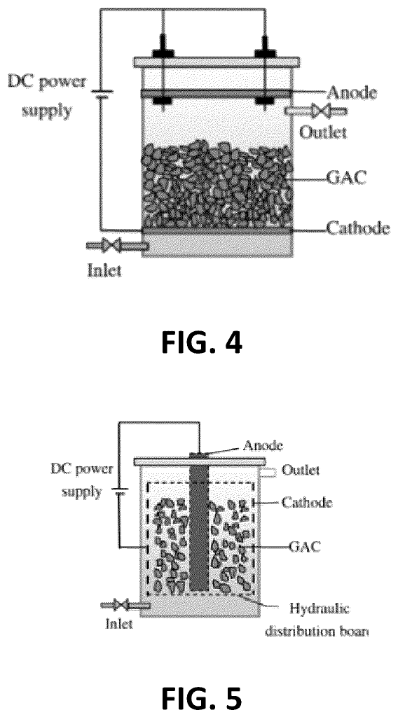

100 g of doped diamond particles having a diameter of 1 μmm was loaded in a cathode electrode frame and the anode electrode rod was inserted into the cathode frame (FIG. 5). A boron-doped diamond plate electrode was used as the anode and a titanium plate was used as the cathode. Then, in a three-dimensional electrolysis system for water treatment, the module described in this example was used to degrade 1 L of a glucose solution with an initial COD of about 9000 mg/L for 4 hrs, during which the degradation current was 1.5 A. The COD removal rate reached 99.9%, and the energy consumption per ton of water was about 20.7 kWh/m³. The energy consumption per ton of water by a two-dimensional electrode without the filler was 31.00 kWh/m³. The energy consumption was reduced by about 33.2% compared with the plate electrode.

### Example 7

In Example 7, the doped diamond particles prepared in Example 1 were used as a filler A and the doped diamond particles prepared in Example 3 were used as a filler B. The fillers were fixed between the cathode electrode and the anode electrode in the left-to-right direction by a Nafion film to form a filler module, as shown in FIG. 2. A boron-doped diamond plate electrode was used as the anode and a titanium plate was used as the cathode. 100 g of mixed doped diamond particles were weighed, in which the ratio of the filler A to the filler B was 1:1. The filler was sandwiched between the anode electrode and the cathode electrode in the top-to-bottom direction without fixation (as shown in FIG. 4). A boron-doped diamond plate electrode was used as the anode and a titanium plate was used as the cathode. Then, in a three-dimensional electrolysis system for water treatment, the module described in this example was used to degrade 1 L of a glucose solution with an initial COD of about 9000 μmg/L for 4 hrs, during which the degradation current was 1.5 A. The COD removal rate reached 99.9%, and the energy consumption per ton of water was about 15.2 kWh/m³. The energy consumption per ton of water by a two-dimensional electrode without the filler was 31.00 kWh/m³. The energy consumption was only 50.97% of the energy consumption of a two-dimensional electrode without the filler.

### Example 8

### Step 1

Filler A:Preparation of doped diamond particles with increasing boron over gradients:
(1) Boron-containing diamond particles with an average particle size of 250 μm were washed.
(2) Then, they were immersed in a suspension containing nano-diamond, ultrasonically shaken for 30 μmin, washed and dried. In the suspension containing nano-diamond, the mass fraction of nano-diamond is 0.1 wt %.
(3) A boron-doped diamond film was deposited by hot-filament CVD. The deposition process parameters were as follows. The hot-filament distance was 6 μmm, the growth temperature was 850° C., the hot-filament temperature was 2200° C., and the deposition pressure was 4 KPa. The growth process was repeated 3 times. Each deposition continued for 5 hrs. Between experiments, the carrier particles were taken out to shake for a while and then put back in the furnace, and each deposition continued for 4 hrs. The thickness of the diamond film obtained was 10 μm. During the first growth and deposition process, the ratio of the mass flow rate of the gases introduced was controlled such that hydrogen: methane: borane=98:2: 0.2. During the second growth and deposition process, the ratio of the mass flow rate of the gases introduced was controlled such that hydrogen: methane: borane=98:2: 0.5. During the third growth and deposition process, the ratio of the mass flow rate of the gases introduced was controlled such that hydrogen: methane: borane=98:2: 0.8.
Filler B: Preparation of doped diamond particles with decreasing boron over gradients:
Spherical silicon carbide having a diameter of 4 μmm was used as the core material. The core material was immersed in a suspension containing nano-diamond, ultrasonically shaken for 30 μmin, washed and dried. In the suspension containing nano-diamond, the mass fraction of nano-diamond is 0.01 wt %.

A boron-doped diamond film was deposited by hot-filament CVD. The deposition process parameters were as follows. The hot-filament distance was 6 μmm, the growth temperature was 800° C., the hot-filament temperature was 2200° C., and the deposition pressure was 3 KPa, and the growth pressure was 2 Kpa. The growth process was repeated 3 times. Between experiments, the carrier particles were taken out to shake for a while and then put back in the furnace, and each deposition continued for 4 hrs. The thickness of the diamond film was 2 μm by controlling the deposition time. During the first growth and deposition process, the ratio of the mass flow rate of the gases introduced was controlled such that hydrogen: methane: borane=98:2: 0.8. During the second growth and deposition process, the ratio of the mass flow rate of the gases introduced was controlled such that hydrogen: methane: borane=98:2: 0.5. During the third growth and deposition process, the ratio of the mass flow rate of the gases introduced was controlled such that hydrogen: methane : borane=98:2: 0.2.

### Step 2: Assembly of a Three-Dimensional Electrode

100 g of mixed doped diamond particles were weighed, in which the ratio of the filler A to the filler B was 1:1. The filler was loaded in a cathode electrode frame and the anode electrode rod was inserted into the cathode frame (FIG. 5). A boron-doped diamond plate electrode was used as the anode and a titanium plate was used as the cathode. 100 g of mixed doped diamond particles were weighed, in which the ratio of the filler A to the filler B was 1:1. The filler was sandwiched between the anode electrode and the cathode electrode in the top-to-bottom direction without fixation (as shown in FIG. 4). A boron-doped diamond plate electrode was used as the anode and a titanium plate was used as the cathode. Then, in a three-dimensional electrolysis system for water treatment, the module described in this example was used to degrade 1 L of a glucose solution with an initial COD of about 9000 μmg/L for 4 hrs, during which the degradation current was 1.5 A. The COD removal rate reached 99.9%, and the energy consumption per ton of water was about 13.7 kWh/m³. The energy consumption per ton of water by a two-dimensional electrode without the filler was 31 kWh/m³. The energy consumption is less than half of the energy consumption of the two-dimensional electrode without the filler.

### Example 9

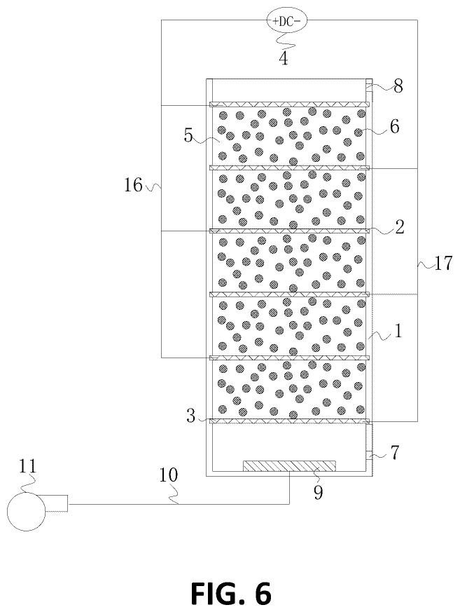

The preparation of doped diamond particles in Example 9 was the same as that in Example 1, except that the doped diamond particles were fixed in a titanium mesh cage by a Nafion film to form a modular unit. Several modular units were superimposed, where the positive electrode was connected to the titanium plate at the joint of the module, and the negative electrode was connected to a cylindrical wall of the module. As shown in FIG. 6, six modular units of this example were superimposed. The total surface area of the titanium mesh was six times that of the titanium mesh in Example 1, and the total surface area of the filled doped diamond particles was 2250 cm². Then, in a three-dimensional electrolysis system for water treatment, the superimposed modules were used to degrade 1 L of a glucose solution with an initial COD of about 9000 μmg/L for 3.5 hrs, during which the degradation current was 1.5 A. The COD removal rate reached 99.9%, and the energy consumption per ton of water was 10 kWh/m³. The energy consumption per ton of water by a two-dimensional electrode without the filler was 31 kWh/m³. The energy consumption per ton of water was reduced by about 67.8% compared with the plate electrode.

### Example 10

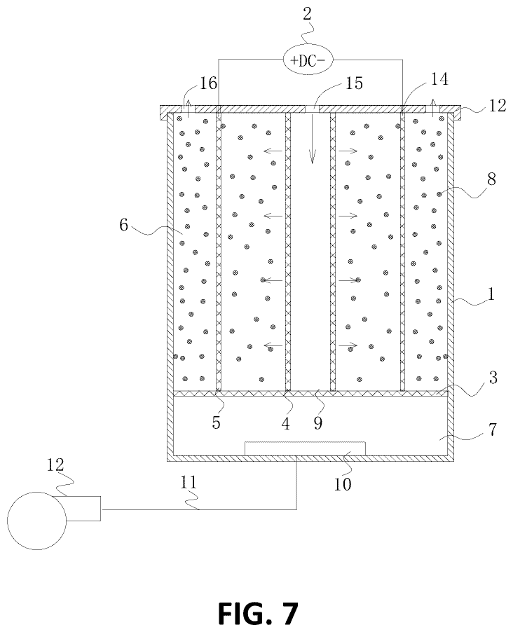

The preparation of doped diamond particles in Example 10 was the same as that in Example 1, except that the doped diamond particles were filled in a cylindrical titanium mesh, including an anode titanium mesh, an intermediate titanium mesh and a cathode titanium mesh. The doped diamond particles were filled between the anode titanium mesh and the intermediate titanium mesh and between the intermediate titanium mesh and the cathode titanium mesh. The total surface area of the titanium mesh was two times that in Example 1, and the total area of the filled doped diamond particles was 750 cm². As shown in FIG. 7, then in a three-dimensional electrolysis system for water treatment, the module described in this example was used to degrade 1 L of a glucose solution with an initial COD of about 9000 μmg/L for 3.5 hrs, during which the degradation current was 1.5 A. The COD removal rate reached 99.9%, and the energy consumption per ton of water was 12.3 kWh/m³. The energy consumption per ton of water by a two-dimensional electrode without the filler was 31.00 kWh/m³. The energy consumption per ton of water was reduced by about 60% compared with the plate electrode.

What is claimed is:

1. A doped diamond particle-based three-dimensional electrode for water treatment, comprising: an anode, a cathode, and a filler, the filler being doped diamond particles, and the doped diamond particles comprising a core material, and a doped diamond film coating the core material, wherein the doping element is one or more selected from boron, nitrogen, phosphorus, and lithium.

2. The doped diamond particle-based three-dimensional electrode for water treatment according to claim 1, wherein the anode is a boron-doped diamond plate electrode or a titanium mesh, the cathode is a titanium plate or a titanium mesh, and the filler is assembled to form a filler module.

3. The doped diamond particle-based three-dimensional electrode for water treatment according to claim 1, wherein
the core material is at least one selected from diamond particles, boron-doped diamond particles, metal particles, and ceramic particles; the metal in the metal particles is one selected from nickel, niobium, copper, titanium, cobalt, tungsten, molybdenum, chromium, and iron or an alloy thereof, the ceramic in the ceramic particles is at least one selected from Al₂O₃, ZrO₂, SiC, Si₃N₄, BN, B₄C, AlN, WC, and Cr₇C₃; the core material has a regular or irregular shape with a size of 100 nm to 50 μmm;
the dopant density in the doped diamond film is >10²¹ cm⁻³, and
the thickness of the doped diamond film is 5 nm-20 μm, and the crystal structure is polycrystalline; and
the doping method of the doped diamond film comprises one of constant doping, multi-layer variable doping and gradient doping or a combination thereof.

4. The doped diamond particle-based three-dimensional electrode for water treatment according to claim 3, wherein the core material is selected from one of 100-500 μm irregular boron-doped diamond particles or diamond particles and 200 nm-30 μmm spherical SiC particles.

5. The doped diamond particle-based three-dimensional electrode for water treatment according to claim 4, wherein when diamond particles and boron-doped diamond particles are used as a core material, the doping method of the doped diamond film coated on the surface of the core material is gradient doping, and the dopant density increases from the inside to the outside; and when the SiC particles are used as a core material, the doping method of the doped diamond film coated on the surface of the core material is gradient doping, and the dopant density decreases from the inside to the outside.

6. The doped diamond particle-based three-dimensional electrode for water treatment according to claim 1, wherein the doped diamond film is a porous doped diamond film, and the pore size in the doped diamond film is 10 nm-200 nm; and
a modification layer is provided on the surface of the coating layer, and the modification layer is one selected from end group modification, metal modification, carbon material modification, and organic modification, or a combination thereof.

7. A method for preparing the doped diamond particle-based three-dimensional electrode for water treatment according to claim 1, comprising the following steps:
Step 1: preparation of doped diamond particles, comprising
planting nano-diamond seed crystal on the surface of the core material, and then growing a doped diamond film on the core material planted with the diamond seed crystal by chemical vapor deposition to obtain doped diamond particles, wherein the growth pressure is 2-5 Kpa; the growth temperature is 800-850° C.; the growth process is repeated 2-6 times, and between experiments, the carrier particles were taken out to shake for a while and then put back in the furnace, and each deposition continued for 3-6 hrs; and the doping gas source is at least one selected from phosphine, ammonia, and borane; and
Step 2: preparation of three-dimensional electrode for water treatment, comprising:
assembling the doped diamond particles into a filler module through a fixed bed or a fluidized bed, and using a boron-doped diamond plate electrode as an anode and a titanium plate as a cathode to obtain the three-dimensional electrode for water treatment.

8. The method for preparing the doped diamond particle-based three-dimensional electrode for water treatment according to claim 7, wherein
in Step 1, when the doping mode is constant doping, during the chemical vapor deposition, the ratio of the mass flow rate of the gases introduced is hydrogen: methane:doping gas source=98:2: 0.3-0.6;
in Step 1, when the doping mode is gradient doping and the dopant density increases from the inside to the outside, during the chemical vapor deposition, the growth time is repeated three times, during the first growth and deposition process, the ratio of the mass flow rate of the gases introduced is controlled such that hydrogen: methane:doping gas source=98:2: 0.1-0.3, during the second growth and deposition process, the ratio of the mass flow rate of the gases introduced is controlled such that hydrogen: methane:doping gas source=98:2: 0.4-0.6, and during the third growth and deposition process, the ratio of the mass flow rate of the gases introduced is controlled such that hydrogen: methane:doping gas source=98:2: 0.7-1.0; and
in Step 1, when the doping mode is gradient doping and the dopant density decreases from the inside to the outside, during the chemical vapor deposition, the growth time is repeated three times, during the first growth and deposition process, the ratio of the mass flow rate of the gases introduced is controlled such that hydrogen: methane:doping gas source=98:2: 0.7-1.0, during the second growth and deposition process, the ratio of the mass flow rate of the gases introduced is controlled such that hydrogen: methane:doping gas source=98:2: 0.4-0.6, and during the third growth and deposition process, the ratio of the mass flow rate of the gases introduced is controlled such that hydrogen: methane:doping gas source=98:2: 0.1-0.3.

9. The method for preparing the doped diamond particle-based three-dimensional electrode for water treatment according to claim 7, wherein
in Step 1, the doped diamond particles are etched, to obtain a porous doped diamond film The etching process includes at least one of high-temperature atmosphere etching, high-temperature metal etching, and plasma etching.

10. The method for preparing the doped diamond particle-based three-dimensional electrode for water treatment according to claim 7, wherein
in Step 2, the fixed bed is assembled by fixing doped diamond particles between the cathode electrode and the anode electrode in the top-to-bottom direction by a Nafion film to form a filler module, or fixing diamond particles by a Nafion film to form a module, inserting the cathode electrode into the Nafion film, and arranging the anode electrode at the right side of the electrode module; and
in Step 2, the fluidized bed is assembled by sandwiching doped diamond particles between the anode electrode and the cathode electrode in the top-to-bottom direction without fixation, or loading doped diamond particles in a cathode electrode frame and inserting the anode electrode rod into the cathode frame.

11. A method for preparing the doped diamond particle-based three-dimensional electrode for water treatment according to claim 2, comprising the following steps:
Step 1: preparation of doped diamond particles, comprising
planting nano-diamond seed crystal on the surface of the core material, and then growing a doped diamond film on the core material planted with the diamond seed crystal by chemical vapor deposition to obtain doped diamond particles, wherein the growth pressure is 2-5 Kpa; the growth temperature is 800-850° C.; the growth process is repeated 2-6 times, and between experiments, the carrier particles were taken out to shake for a while and then put back in the furnace, and each deposition continued for 3-6 hrs; and the doping gas source is at least one selected from phosphine, ammonia, and borane; and
Step 2: preparation of three-dimensional electrode for water treatment, comprising:
assembling the doped diamond particles into a filler module through a fixed bed or a fluidized bed, and using a boron-doped diamond plate electrode as an anode and a titanium plate as a cathode to obtain the three-dimensional electrode for water treatment.

12. A method for preparing the doped diamond particle-based three-dimensional electrode for water treatment according to claim 3, comprising the following steps:
Step 1: preparation of doped diamond particles, comprising
planting nano-diamond seed crystal on the surface of the core material, and then growing a doped diamond film on the core material planted with the diamond seed crystal by chemical vapor deposition to obtain doped diamond particles, wherein the growth pressure is 2-5 Kpa; the growth temperature is 800-850° C.; the growth process is repeated 2-6 times, and between experiments, the carrier particles were taken out to shake for a while and then put back in the furnace, and each deposition continued for 3-6 hrs; and the doping gas source is at least one selected from phosphine, ammonia, and borane; and
Step 2: preparation of three-dimensional electrode for water treatment, comprising:
assembling the doped diamond particles into a filler module through a fixed bed or a fluidized bed, and using a boron-doped diamond plate electrode as an anode and a titanium plate as a cathode to obtain the three-dimensional electrode for water treatment.

13. A method for preparing the doped diamond particle-based three-dimensional electrode for water treatment according to claim 4, comprising the following steps:
Step 1: preparation of doped diamond particles, comprising
planting nano-diamond seed crystal on the surface of the core material, and then growing a doped diamond film on the core material planted with the diamond seed crystal by chemical vapor deposition to obtain doped diamond particles, wherein the growth pressure is 2-5 Kpa; the growth temperature is 800-850° C.; the growth process is repeated 2-6 times, and between experiments, the carrier particles were taken out to shake for a while and then put back in the furnace, and each deposition continued for 3-6 hrs; and the doping gas source is at least one selected from phosphine, ammonia, and borane; and
Step 2: preparation of three-dimensional electrode for water treatment, comprising:
assembling the doped diamond particles into a filler module through a fixed bed or a fluidized bed, and using a boron-doped diamond plate electrode as an anode and a titanium plate as a cathode to obtain the three-dimensional electrode for water treatment.

14. A method for preparing the doped diamond particle-based three-dimensional electrode for water treatment according to claim 5, comprising the following steps:
Step 1: preparation of doped diamond particles, comprising
planting nano-diamond seed crystal on the surface of the core material, and then growing a doped diamond film on the core material planted with the diamond seed crystal by chemical vapor deposition to obtain doped diamond particles, wherein the growth pressure is 2-5 Kpa; the growth temperature is 800-850° C.; the growth process is repeated 2-6 times, and between experiments, the carrier particles were taken out to shake for a while and then put back in the furnace, and each deposition continued for 3-6 hrs; and the doping gas source is at least one selected from phosphine, ammonia, and borane; and
Step 2: preparation of three-dimensional electrode for water treatment, comprising:
assembling the doped diamond particles into a filler module through a fixed bed or a fluidized bed, and using a boron-doped diamond plate electrode as an anode and a titanium plate as a cathode to obtain the three-dimensional electrode for water treatment.

15. A method for preparing the doped diamond particle-based three-dimensional electrode for water treatment according to claim 6, comprising the following steps:
Step 1: preparation of doped diamond particles, comprising
planting nano-diamond seed crystal on the surface of the core material, and then growing a doped diamond film on the core material planted with the diamond seed crystal by chemical vapor deposition to obtain doped diamond particles, wherein the growth pressure is 2-5 Kpa; the growth temperature is 800-850° C.; the growth process is repeated 2-6 times, and between experiments, the carrier particles were taken out to shake for a while and then put back in the furnace, and each deposition continued for 3-6 hrs; and the doping gas source is at least one selected from phosphine, ammonia, and borane; and
Step 2: preparation of three-dimensional electrode for water treatment, comprising:
assembling the doped diamond particles into a filler module through a fixed bed or a fluidized bed, and using a boron-doped diamond plate electrode as an anode and a titanium plate as a cathode to obtain the three-dimensional electrode for water treatment.

16. The method for preparing the doped diamond particle-based three-dimensional electrode for water treatment according to claim 11, wherein
in Step 1, when the doping mode is constant doping, during the chemical vapor deposition, the ratio of the mass flow rate of the gases introduced is hydrogen: methane:doping gas source=98:2: 0.3-0.6;
in Step 1, when the doping mode is gradient doping and the dopant density increases from the inside to the outside, during the chemical vapor deposition, the growth time is repeated three times, during the first growth and deposition process, the ratio of the mass flow rate of the gases introduced is controlled such that hydrogen: methane:doping gas source=98:2: 0.1-0.3, during the second growth and deposition process, the ratio of the mass flow rate of the gases introduced is controlled such that hydrogen: methane:doping gas source=98:2: 0.4-0.6, and during the third growth and deposition process, the ratio of the mass flow rate of the gases introduced is controlled such that hydrogen: methane:doping gas source=98:2: 0.7-1.0; and
in Step 1, when the doping mode is gradient doping and the dopant density decreases from the inside to the outside, during the chemical vapor deposition, the growth time is repeated three times, during the first growth and deposition process, the ratio of the mass flow rate of the gases introduced is controlled such that hydrogen: methane:doping gas source=98:2: 0.7-1.0, during the second growth and deposition process, the ratio of the mass flow rate of the gases introduced is controlled such that hydrogen: methane:doping gas source=98:2: 0.4-0.6, and during the third growth and deposition process, the ratio of the mass flow rate of the gases introduced is controlled such that hydrogen: methane:doping gas source=98:2: 0.1-0.3.

17. The method for preparing the doped diamond particle-based three-dimensional electrode for water treatment according to claim 11, wherein
in Step 1, the doped diamond particles are etched, to obtain a porous doped diamond film The etching process includes at least one of high-temperature atmosphere etching, high-temperature metal etching, and plasma etching.

18. The method for preparing the doped diamond particle-based three-dimensional electrode for water treatment according to claim 11, wherein
in Step 2, the fixed bed is assembled by fixing doped diamond particles between the cathode electrode and the anode electrode in the top-to-bottom direction by a Nafion film to form a filler module, or fixing diamond particles by a Nafion film to form a module, inserting the cathode electrode into the Nafion film, and arranging the anode electrode at the right side of the electrode module; and
in Step 2, the fluidized bed is assembled by sandwiching doped diamond particles between the anode electrode and the cathode electrode in the top-to-bottom direction without fixation, or loading doped diamond particles in a cathode electrode frame and inserting the anode electrode rod into the cathode frame.

19. The method for preparing the doped diamond particle-based three-dimensional electrode for water treatment according to claim 12, wherein
in Step 1, when the doping mode is constant doping, during the chemical vapor deposition, the ratio of the mass flow rate of the gases introduced is hydrogen: methane:doping gas source=98:2: 0.3-0.6;
in Step 1, when the doping mode is gradient doping and the dopant density increases from the inside to the outside, during the chemical vapor deposition, the growth time is repeated three times, during the first growth and deposition process, the ratio of the mass flow rate of the gases introduced is controlled such that hydrogen: methane:doping gas source=98:2: 0.1-0.3, during the second growth and deposition process, the ratio of the mass flow rate of the gases introduced is controlled such that hydrogen: methane:doping gas source=98:2: 0.4-0.6, and during the third growth and deposition process, the ratio of the mass flow rate of the gases introduced is controlled such that hydrogen: methane:doping gas source=98:2: 0.7-1.0; and
in Step 1, when the doping mode is gradient doping and the dopant density decreases from the inside to the outside, during the chemical vapor deposition, the growth time is repeated three times, during the first growth and deposition process, the ratio of the mass flow rate of the gases introduced is controlled such that hydrogen: methane:doping gas source=98:2: 0.7-1.0, during the second growth and deposition process, the ratio of the mass flow rate of the gases introduced is controlled such that hydrogen: methane:doping gas source=98:2: 0.4-0.6, and during the third growth and deposition process, the ratio of the mass flow rate of the gases introduced is controlled such that hydrogen: methane:doping gas source=98:2: 0.1-0.3.

20. The method for preparing the doped diamond particle-based three-dimensional electrode for water treatment according to claim 12, wherein
in Step 1, the doped diamond particles are etched, to obtain a porous doped diamond film The etching process includes at least one of high-temperature atmosphere etching, high-temperature metal etching, and plasma etching.
